(19) United States
(12) Patent Application Publication
(10) Pub. No.: US 2009/0160474 A1
(43) Pub. Date: Jun. 25, 2009

(54) PRINTED CIRCUIT BOARD AND IMPEDANCE GUARANTEE METHOD OF PRINTED CIRCUIT BOARD

(75) Inventor: Yuichi Koga, Hachioji-shi (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/258,175

(22) Filed: Oct. 24, 2008

(30) Foreign Application Priority Data
Dec. 21, 2007 (JP) 2007-331052

(51) Int. Cl. G01R 27/02; H05K 1/02

(52) U.S. Cl. 324/763; 174/250

(57) ABSTRACT

According to one embodiment, a printed circuit board includes a coupon portion having, for each of a plurality of signal layers, an impedance guarantee coupon as a reference for the layer, and a product portion having, in at least one of the plurality of signal layers, a transmission line requiring impedance guarantee having an impedance decision factor different from the coupon formed in the coupon portion, wherein an impedance of the transmission line is guaranteed on the basis of a known impedance decision factor of the transmission line and a measured value of the coupon.

### CROSS-REFERENCE TO RELATED APPLICATIONS

This application is based upon and claims the benefit of priority from Japanese Patent Application No. 2007-331052, filed Dec. 21, 2007, the entire contents of which are incorporated herein by reference.

### BACKGROUND

1. Field

One embodiment of the present invention relates to a printed circuit board comprising a transmission line requiring impedance guarantee, and an impedance guarantee method of the printed circuit board.

2. Description of the Related Art

Recently, in electronic apparatuses, the speed of transmission between circuit elements in the electronic apparatuses is increasing, and the impedance control technique for transmission circuits or lines between the elements is an important factor for maintaining the stability of transmission of signals via the transmission circuits.

In a high-frequency signal transmission circuit, signals can be propagated with a maximum energy by controlling the impedance (high-frequency impedance) of the circuit.

In the electronic apparatuses described above, circuit elements for processing high-frequency signals are mounted on a printed circuit board. This makes impedance control of the printed circuit board indispensable.

The impedance of a transmission line on the printed circuit board is controlled by various parameters such as the width and thickness of the transmission line, and the dielectric constant and thickness of a core or a base made of a prepreg, for example.

The impedance to be controlled is roughly classified into a single-end impedance (to be referred to as Z0 hereinafter) and a differential impedance (to be referred to as Zdiff hereinafter) in accordance with the transmission line characteristics.

The printed circuit board (impedance board) as an object of the impedance control as described above comprises a product portion incorporated into a product as a circuit board having circuit elements mounted thereon, and a coupon portion prepared for impedance checking, by measurements, whether the impedance to be guaranteed of a transmission line of the product portion falls within the range of rated values.

A multilayered printed circuit board has a surface-layer wiring portion and inner-layer wiring portion, and wiring patterns (high-speed signal transmission lines) for the high-speed signal transmission are formed as a signal layer on the surface layer wiring portion and as a signal layer on the inner layer wiring portion. In the multilayered printed circuit board, a power supply layer and ground (GND) layer (plane) are normally formed in the inner layer with signal layers interposed between them. In the product portion of the multilayered printed circuit board, a plurality of circuit elements for processing high-speed signals in the high-frequency band are mounted, and transmission lines (high-speed signal transmission lines) of these circuit elements are formed in the individual signal layers. The impedance value of this transmission line is defined for each circuit. As an example, the central value and an allowable value range of the impedance is defined like [Z0=55Ω±10%], for example.

When shipping the printed circuit board or before supplying it to a circuit element mounting line, the impedance value is actually measured by using a measurement coupon formed in the coupon portion of the printed circuit board, thereby checking whether the above-mentioned impedance falls within the range of allowable values.

Conventionally, the measurement coupon is prepared in the coupon portion for each line type of all transmission lines including the surface layers and inner layers as objects of impedance guarantee. For example, when a Z0 surface-layer wiring, Z0 inner-layer wiring, Zdiff surface-layer wiring, and Zdiff inner-layer surface wiring (two types) exist in the product portion, test coupons for the Z0 surface-layer wiring, Z0 inner-layer wiring, Zdiff surface-layer wiring, and Zdiff inner-layer wiring (two types) are prepared in the coupon portion. An impedance guarantee test (measurement) is performed for each transmission line by actually measuring the corresponding coupon. Accordingly, the impedance measurements using a large number of coupons require much labor and time.

For the printed circuit board having such a kind of the coupon region, a coupon technique including, in the impedance measurement region as the coupon portion, circuits for measuring the upper and lower limits of impedance that can occur in a wiring of the product portion conventionally exists (e.g., Jpn. Pat. Appln. KOKAI Publication No. 2002-359451). Also, a coupon technique that increases the matching characteristics between the product portion and test coupon portion by forming ungrounded parallel dummy patterns on the two sides of a measurement signal line exists (Jpn. Pat. Appln. KOKAT Publication No. 2005-197556, for example).

The conventional coupon techniques described above can be effective means when the number of line types requiring impedance guarantee is as small as one or two in the product portion. If the number of line types requiring impedance guarantee increases, however, the area occupied by the coupon region on the entire board significantly increases accordingly, thereby producing a large effect on the product cost and productivity.

As described above, the conventional coupon techniques require one or a plurality of types of coupons for each line type as an object of impedance guarantee in the product portion, thereby significantly increasing the ratio of the area of the coupon portion to that of the product portion on the printed circuit board. This affects largely on the product cost and productivity.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is a view showing the arrangement of a printed circuit board according to an embodiment of the present invention;

FIG. 2 is a view showing an example of a stack of the printed circuit board according to the embodiment;

FIG. 3 is a view showing the impedance constituent elements of the printed circuit board according to the embodiment;

FIG. 4 is a view showing the impedance constituent elements of the printed circuit board according to the embodiment; and

FIG. 5 is a flowchart showing the fabrication steps of the printed circuit board according to the embodiment.

### DETAILED DESCRIPTION

Various embodiments according to the present invention will be hereinafter described with reference to the accompanying drawings. In general, according to one embodiment of the invention, a printed circuit board comprising: a coupon portion having, for each of a plurality of signal layers, an impedance guarantee coupon as a basis for the layer; and a product portion having, in at least one of the plurality of signal lines, a transmission line requiring impedance guarantee having an impedance decision factor different from the coupon formed in the coupon portion, wherein an impedance of the transmission line is guaranteed on the basis of a known impedance decision factor of the transmission line and a measured value of the coupon.

Embodiments of the present invention will be explained below with reference to the accompanying drawing. Note that in an actual application, impedance guarantee is performed for all signal layers formed on a multilayered printed circuit board. To simplify the explanation, however, an arrangement in which impedance guarantee is performed for two signal layers including a surface layer will be described as an example.

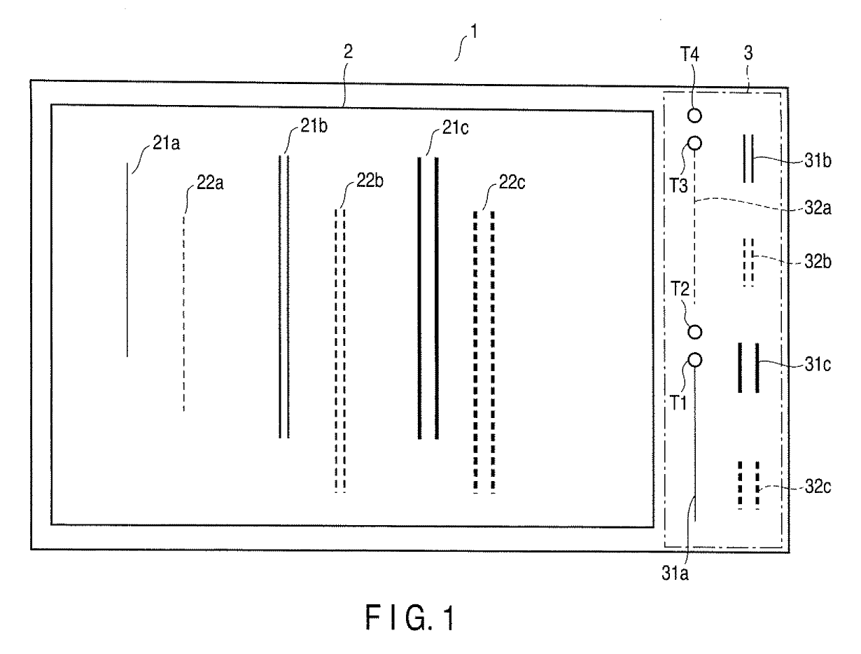

As shown in FIG. 1, a multilayered printed circuit board 1 according to an embodiment of the present invention comprises a product portion 2 incorporated into a product as a circuit board by part mounting, and a coupon portion 3 for checking, by measurement, whether the impedances to be guaranteed of transmission lines of the product portion 2 fall within the range of defined values.

In the product portion 2, transmission lines each requiring impedance guarantee are formed in a plurality of layers in the multilayered printed circuit board 1, respectively. In the embodiment shown in FIG. 1, as transmission lines requiring impedance guarantee, three types of transmission lines 21a, 21b, and 21c indicated by the solid lines are formed in a signal layer on the surface layer side, and three types of transmission lines 22a, 22b, and 22c indicated by the broken lines are formed in a signal layer on the inner layer side. Of the transmission lines 21a, 21b, 21c, 22a, 22b, and 22c, the impedance of each of the transmission lines 21a and 22a can be guaranteed by only a coupon in the coupon portion 3, and each of the remaining transmission lines 21b, 21c, 22b, and 22c requires impedance guarantee having an impedance decision factor different from the coupon formed in the coupon portion 3. The transmission lines 21b, 21c, 22b, and 22c requiring impedance guarantee having the impedance decision factor different from the coupon will be called dissimilar transmission lines hereinafter.

In the coupon portion 3, an impedance guarantee coupon is formed in each of the signal layer on the surface layer side and the signal layer on the inner layer side as a reference impedance coupon. In addition, the coupon portion 3 has dummy lines (having line width measurement patterns) corresponding to the line types of the transmission lines requiring impedance guarantee having an impedance decision factor different from the coupon formed in the coupon portion 3. In the embodiment shown in FIG. 1, as an impedance guarantee coupon with a reference impedance for a layer, an impedance guarantee coupon 31a corresponding to the transmission line 21a of the product portion 2 and an impedance guarantee coupon 32a corresponding to the transmission line 22a of the product portion 2 are formed. The impedance guarantee coupons 31a and 32a have measurement terminals T1, T2 for connecting a probe. Dummy lines 31b, 31c, 32b, and 32c corresponding to the dissimilar transmission lines 21b, 21c, 22b, and 22c of the product portion 2 are also formed in the coupon portion 3. The dummy lines 31b, 31c, 32b, and 32c are formed by conductor patterns having a minimum length (e.g., about 10 mm) of which the line width can be measured (while the line-length direction can be recognized) by, e.g., AOI (Automated Optical Inspection).

The transmission line 21a formed in the product portion 2 and the impedance guarantee coupon 31a formed in the coupon portion 3 have equal parameters, including the line width, as impedance decision factors. Likewise, the transmission line 22a and impedance guarantee coupon 32a have equal parameters, including the line width, as impedance decision factors. Accordingly, the impedance of the transmission line 21a can be guaranteed by measuring the impedance guarantee coupon 31a, and that of the transmission line 22a can be guaranteed by measuring the impedance guarantee coupon 32a.

The dissimilar transmission lines 21b, 21c, 22b, and 22c formed in the production portion 2 and the dummy lines 31b, 31c, 32b, and 32c formed in the coupon portion 3 respectively have the same line widths. In this embodiment, the dissimilar transmission lines 21b, 21c, 22b, and 22c are each made up of two parallel transmission lines for transmitting differential signals, so the dummy lines 31b, 31c, 32b, and 32c are also each made up of two parallel transmission lines having the same line distance

Of the transmission lines 21a, 21b, 21c, 22a, 22b, and 22c formed in the product portion 2, no coupon for impedance guarantee is formed in the coupon portion 3 for the dissimilar transmission lines 21b, 21c, 22b, and 22c. For the dissimilar transmission lines 21b, 21c, 22b, and 22c, the impedance is guaranteed on the basis of the measured value of the coupon formed in the coupon portion 3 and the measured value of the line width of the dummy lines. For the dissimilar transmission lines 21b and 21c, the impedance is guaranteed on the basis of the measured value of the impedance guarantee coupon 31a, and the measured value of the line width of the dummy lines 31b and 31c corresponding to the dissimilar transmission lines 21b and 2lc. For the dissimilar transmission lines 22b and 22c, the impedance is guaranteed on the basis of the measured value of the impedance guarantee coupon 32a, and the measured value of the line width of the dummy lines 32b and 32c corresponding to the dissimilar transmission lines 22b and 22c.

As described above, impedance measurement is performed only once for each layer, and the impedances of the remaining transmission lines or dissimilar transmission lines are guaranteed on the basis of only the measurement results of the above impedance measurements and the line widths measured in the fabrication steps.

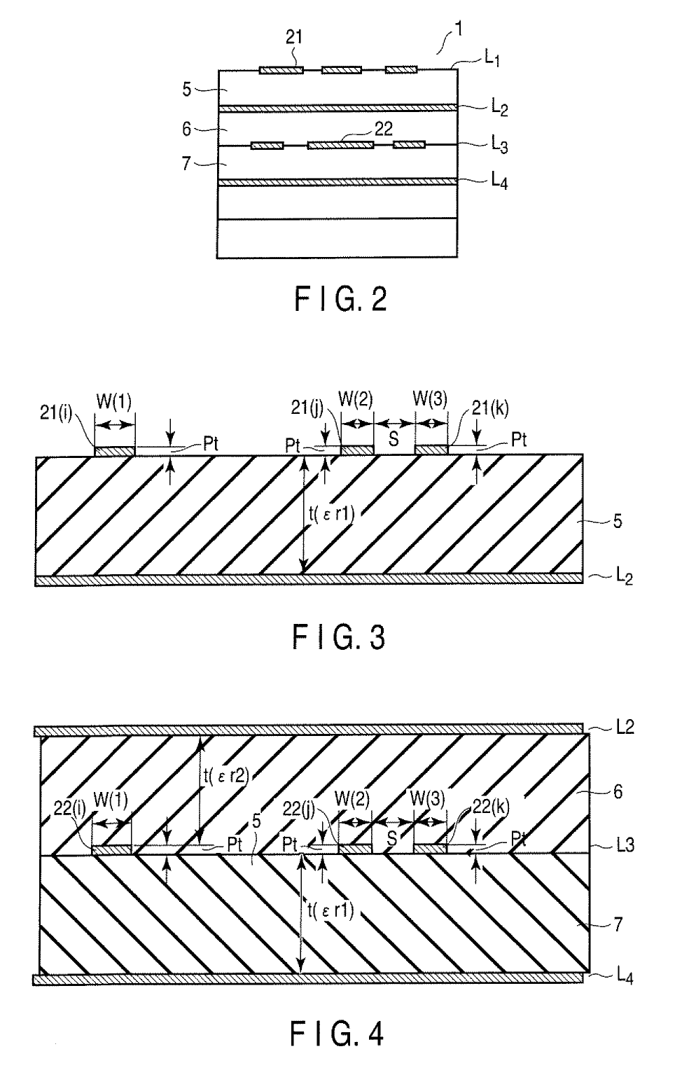

The constituent elements of the impedance of the transmission lines will be explained below with reference to FIGS. 2 to 4. Note that Z0 represents the single-end impedance and Zdiff represents the differential impedance in this explanation as well.

FIG. 2 shows an example of a stacked structure of a multilayered printed circuit board. Stacked insulating layers 5, 6, and 7 are provided with conductor layers including a first layer L1 to a fourth layer L4. A surface layer as the first layer L1 and an inner layer as the third layer L3 are provided with conductor layers acting as signal layers. The second layer L2 and fourth layer L4 each form a power supply plane or ground (GND) plane. The dielectric constant (εr) of the insulating layers 5, 6, and 7 is determined by the insulating material used.

FIG. 3 shows the impedance constituent elements in the surface layer. FIG. 4 shows the impedance constituent elements in the inner layer.

Referring to FIG. 3, the insulating layer 5 having a specific dielectric constant ε_1 and a thickness t (εr1) is stacked on the power supply/GND layer L2.

A single-end, surface-layer signal pattern 21(i) having a thickness Pt is formed on the insulating layer 5 to have a line width W(1) in order to achieve a designated impedance. Similarly, in order to achieve a designated impedance, differential signal patterns 21(j) and 21(k) having the thickness Pt are formed parallel to have line widths W(2) and W(3), respectively, with a predetermined spacing S being held.

The single-end impedance (Z0) has the following relationship.

Z0=fx (εr_1, insulating layer thickness t(εr1) line width W(1), and wiring thickness Pt)

The differential impedance (Zdiff) has the following relationship.

Zdiff=fx (εr_1, insulating layer thickness t(εr1), line widths W(2) and W(3), wiring spacing S, and wiring thickness Pt)

In the case of the inner-layer wiring shown in FIG. 4, a single-end, surface-layer signal pattern 22(i) and differential signal patterns 22(j) and 22(k) are formed in the conductor layer L3 on the insulating layer 7. The insulating layer 6 having a certain specific dielectric constant εr_2 and an insulating layer thickness t(εr2) is stacked on the signal patterns 22(i), 22(j), and 22(k). The power supply/GND layer L2 is formed on the insulating layer 6. Therefore, the relations are as follows.

Z0=fx (εr_1, insulating layer thickness t(εr1), εr_2, insulating layer thickness t(εr2), line width W(1), and wiring thickness Pt)

Zdiff=fx (εr_1, insulating layer thickness t(εr1), εr_2, insulating layer thickness t(εr2), line widths W(2) and W(3), wiring spacing S, and wiring thickness Pt)

Noting the above relations, the present invention classifies the parameters into those determined on the basis of the materials, and those determined during fabrication. The parameters determined during fabrication are automatically measured by using AOI or the like in the fabrication steps, thereby guaranteeing the impedance without any coupon. Also, to correct the measurement error and measure the actual impedance as a reference, an impedance measurement coupon is prepared in only one point of each layer and measured.

This measurement is also used to calculate back immeasurable items (non-destructive measurement of the insulating layer thickness is difficult, for example). That is,

Z0=fx (εr_1, insulating layer thickness t(εr1), εr_2, insulating layer thickness t(εr2), line width W(1), and wiring thickness Pt).

When the insulating layer thickness t(εr2) is immeasurable and undetermined in the above relation, the insulating layer thickness t (εr2) can be determined by using an inverse function if the measured value of Z0 is known. By using the parameters thus obtained and the measured parameters, it is possible to guarantee the impedances of the dissimilar transmission lines 21b, 21c, 22b, and 22c having no coupon prepared as shown in FIG. 1.

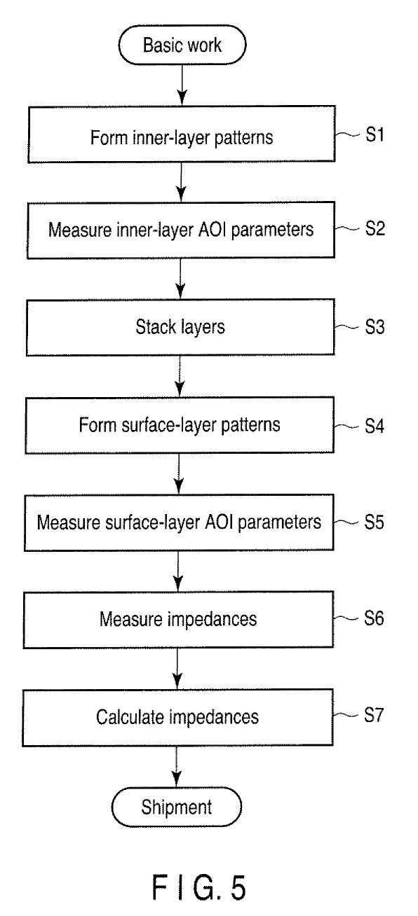

FIG. 5 is a flowchart showing the fabrication steps of the printed circuit board 1 shown in FIG. 1 capable of this impedance guarantee. In the fabrication steps of the multilayered printed circuit board 1, whenever inner-layer patterns such as the patterns 22(a), 22(b), 22(c) shown in FIG. 1 are formed, the parameters of the inner-layer pattern are measured in accordance with predetermined fabrication standards by using AOI or the like (steps S1 and S2). In this step S2, the line widths of the dummy lines 32b and 32c are measured.

Surface-layer patterns such as the patterns 21(a), 21(b), 21(c) are formed (step S4) after a predetermined number of stacking steps (steps S1 to S3), and the same measurement as described above is performed on this surface-layer patterns (step S5). In this step (S5), the line widths of the dummy lines 31b and 31c are measured.

After the above steps, impedance measurement is performed using the impedance guarantee coupons 31a and 32a of the coupon portion 3, thereby obtaining measured parameter values (step S6). In addition, these measured parameter values and the measured line width values described above are used to perform processing (calculation) of impedance guarantee for the dissimilar transmission lines 21b, 21c, 22b, and 22c.

The impedance guarantee means described above makes it possible to reduce the area (coupon area) occupied by the coupon portion 3 on the multilayered printed circuit board 1, thereby reducing the cost of the product portion 2. It is also possible to guarantee the impedances of various high-speed signal transmission lines. Furthermore, impedance measurement can be simplified because it is unnecessary to actually measure the differential impedance.

Note that in the above embodiment, the dummy lines (line width measurement patterns) of all the dissimilar transmission lines are formed in the coupon portion 3. However, the coupon portion 3 can be further simplified by forming only dummy lines corresponding to inner-layer dissimilar transmission lines in the coupon portion 3, and actually measuring the line widths of dissimilar transmission lines formed in the surface layer. Note also that in the arrangement of the multilayered printed circuit board disclosed in the above embodiment, the main constituent elements are shown as they are simplified in order to facilitate understanding the embodiment of the present invention. When the embodiment is practiced, therefore, these constituent elements can be variously modified and changed without departing from the sprit and scope of the invention.

While certain embodiments of the invention have been described, these embodiments have been presented by way of example only, and are not intended to limit the scope of the invention. Indeed, the novel methods and systems described herein may be embodied in a variety of other forms; furthermore, various omissions, substitutions and changes in the form of the methods and systems described herein may be made without departing from the spirit of the invention. The accompanying claims and their equivalents are intended to cover such forms or modifications as would fall within the scope and spirit of the invention.

What is claimed is:

1. A printed circuit board comprising:
a coupon portion having, for each of a plurality of signal layers, an impedance guarantee coupon as a reference for the layer; and
a product portion having, in at least one of the plurality of signal layers, a transmission line requiring impedance guarantee having an impedance decision factor different from the coupon formed in the coupon portion,
wherein an impedance of the transmission line is guaranteed on the basis of a known impedance decision factor of the transmission line and a measured value of the coupon.

2. The printed circuit board according to claim 1, wherein the known impedance decision factor is a measured value of a line width measured in a fabrication step of the product portion.

3. The printed circuit board according to claim 2, wherein the known impedance decision factor is a measured value of a line width of a dummy line formed in the coupon portion to correspond to the transmission line.

4. The printed circuit board according to claim 3, wherein the dummy line is formed by a conductor pattern having a minimum length of which the line width is measurable.

5. An impedance guarantee method of a printed circuit board having a product portion and a coupon portion, the method comprising:
forming, in the coupon portion, for each of a plurality of signal layers, an impedance guarantee coupon as a reference for the layer;
forming, in the product portion, for at least one of the plurality of signal layers, a transmission line requiring impedance guarantee having an impedance decision factor different from the coupon formed in the coupon portion; and
guaranteeing an impedance of the transmission line on the basis of a known impedance decision factor of the transmission line and a measured value of the coupon.

6. The impedance guarantee method according to claim 5, further comprising forming, in the coupon portion, a dummy line corresponding to a line type of the transmission liner measuring a line width of the dummy line in a fabrication step of the printed circuit board, and using the measured value of the line width as the known impedance decision factor.

7. The impedance guarantee method according to claim 6, wherein the dummy line is formed by a conductor pattern having a minimum length of which the line width is measurable.
